(19) United States
(12) Patent Application Publication
(10) Pub. No.: US 2016/0284751 A1
(43) Pub. Date: Sep. 29, 2016

(54) CHIP SCALE SENSING CHIP PACKAGE AND A MANUFACTURING METHOD THEREOF

(71) Applicant: XINTEC INC., Taoyuan City (TW)

(72) Inventors: Yen-Shih HO, Kaohsiung City (TW); Tsang-Yu LIU, Zhubei City (TW); Po-Han LEE, Taipei City (TW); Jiun-Yen LAI, Taipei City (TW)

(21) Appl. No.: 15/062,020

(22) Filed: Mar. 4, 2016

Related U.S. Application Data
(60) Provisional application No. 62/138,372, filed on Mar. 25, 2015.

(51) Int. Cl. H01L 27/146

(52) U.S. Cl. CPC H01L 27/14618

(57) ABSTRACT

This present invention provides a chip scale sensing chip package, comprising a sensing chip having a first top surface and a first bottom surface opposite to the first top surface, which comprises a sensing device near the first top surface, a plurality of conductive pads near the first top surface and adjacent to the sensing device; a plurality of through holes on the first top surface and each of the through holes exposing one of the conductive pads corresponding to with each other; a plurality of conductive structure formed on the first bottom surface; and a re-distribution layer (RDL) formed on the first bottom surface and the first through holes to respectively connect to each of the conductive pads and each of the conductive structures; a spacing layer, surrounding the sensing chip, formed on the sensing chip. The spacing layer has a second top surface, a second bottom surface and an opening through the second top surface and the second bottom surface, wherein the opening corresponds to the sensing device and the inner wall of the opening remains a desired distance d (d>0) with the sensing device; and a first adhesive layer sandwiched between the second bottom surface of the spacing layer and the first top surface of the sensing chip.

This application claims the benefit of U.S. provisional application No. 62/138,372, filed on Mar. 25, 2015, and the entirety of which is incorporated by reference herein.

### BACKGROUND OF THE INVENTION

1. Field of the Invention

The present invention relates to a sensing chip package, and in particular relates to a chip scale sensing chip package and a manufacturing method thereof.

2. Description of the Related Art

A conventional chip package having sensing functions, such as a fingerprint-recognition chip package, is easily contaminated or damaged during the manufacturing process and results in decreasing both the yield and liability of a conventional chip package having sensing functions. In order to meet the tendency of size-miniaturization of electronic components, it is an import subject to minimize the thickness of a substrate for carrying a semiconductor chip to be packaged. However, if a thin substrate for carrying a semiconductor chip to be packaged is utilized, the yield will be reduced owing to the thin substrate is bended or damaged during the package process.

Moreover, in order to provide good image properties for an image sensing chip package, the sensing device within the image sensing package must keep a suitable distance with the transparent cap layer. To achieve this purpose, the conventional package technology utilizes a spacing layer consisting of photoresist between the sensing device and the transparent cap layer to keep a suitable distance therebetween. However, the thickness of the spacing layer consisting of photoresist is at most 40 μm owing to the limitation of photolithography technology. The light passing through the dust falling on the cap layer of the image sensing device will be twisted or interfered and results in ghost images or light reflections. Besides, the photoresist is sensitive to light and prone to crack, which will reduce the optical efficiencies and stabilities of the sensing chip package.

In order to resolve above-mentioned drawbacks, this present invention discloses a novel chip scale sensing chip package and a manufacturing method thereof, which is characterized by forming a thick spacing layer, comprising silicon, aluminum nitride, glass or ceramic materials, between the cap layer and the sensing chip to remain a greater distance between the cap layer and the sensing chip. Accordingly, the pathway of light from the dust falling on the cap layer to the sensing chip is increased to decrease the abnormal image such as ghost image caused by the dust fall on the cap layer. Besides, the thick spacing layer comprising silicon, aluminum nitride, glass or ceramic materials is not sensitive to light as the photoresist. The optical efficiencies and stabilities of the sensing chip package can be enhanced.

### SUMMARY OF THE INVENTION

A feature of this invention provides a chip scale sensing chip package, comprising a sensing chip with a first top surface and an first bottom surface opposite to each other, which comprises a sensing device formed near the first top surface and a plurality of conductive pads formed near the first top surface and adjacent to the sensing device, a plurality of first through holes formed on the first bottom surface and each of the first through holes exposes its corresponding conductive pad, a plurality of conductive structures formed on the first bottom surface, and a re-distribution layer overlaying the first bottom surface and the first through holes to interconnect each of the conductive pads and each of the conductive structures; a spacing layer, surrounding the sensing chip, formed on the sensing chip, wherein the spacing layer having a second top surface and a second bottom surface opposite to each other, and an opening penetrating through the second top surface and the second bottom surface, and the inner wall of the opening remains a predetermined distance d (d>0) with the sensing device; and a first adhesive layer sandwiched between the second bottom surface of the spacing layer and the first top surface of the sensing chip.

Another feature of this invention provides a chip scale sensing chip package, comprising a sensing chip with a first top surface, a first bottom surface opposite to the first top surface, and a first sidewall and a second sidewall respectively adjoined to the first top surface and the first bottom surface which comprises a sensing device formed near the first top surface, a plurality of conductive pads formed near the first top surface adjacent to the sensing device, wherein the first side wall and the second side wall respectively exposes the edge of each conductive pad thereon, a plurality of conductive structures formed on the first bottom surface, and a re-distribution layer overlaying the first bottom surface and the first, second side walls to interconnect each of the conductive pads and each of the conductive structures; a spacing layer, surrounding the sensing chip, formed on the sensing chip and corresponding to the sensing device, wherein the spacing layer having a second top surface and a second bottom opposite to each other, and an opening penetrating through the second top surface and the second bottom surface, and the inner wall of the opening remains a predetermined distance d (d>0) with the sensing chip; and a first adhesive layer sandwiched between the second bottom surface of the spacing layer and the first top surface of the sensing chip.

Another feature of this invention provides a chip scale sensing chip package as mentioned above, wherein the spacing layer is thicker than the sensing chip.

Another feature of this invention provides a chip scale sensing chip package as mentioned above, wherein the spacing layer comprises the material selected from one or more members of the group consisting of silicon, aluminum nitride, glass and ceramic materials.

Another feature of this invention provides a chip scale sensing chip package as mentioned above, wherein the first adhesive layer comprises the material selected from one or more members of the group consisting of photoresist, polyimide and epoxy resin.

Another feature of this invention provides a chip scale sensing chip package as mentioned above, further comprising a cap layer bonded to the spacing layer by sandwiching a second adhesive layer therebetween.

Another feature of this invention provides a chip scale sensing chip package as mentioned above, wherein the cap layer comprises the material selected from one or more members of the group consisting of glass, sapphire and aluminum nitride and ceramic materials.

Another feature of this invention provides a chip scale sensing chip package as mentioned above, wherein the second adhesive layer comprises the material selected from one or more members of the group consisting of photoresist, polyimide and epoxy resin.

Another feature of this invention provides a chip scale sensing chip package as mentioned above, wherein the conductive structures comprises solder balls, solder bumps and conductive pillars.

### BRIEF DESCRIPTION OF THE DRAWINGS

The present invention can be more fully understood by reading the subsequent detailed description and examples with references made to the accompanying drawings, wherein:

FIGS. 1A˜1F and FIGS. 1E′˜1F′ are cross-sectional views of the exemplary embodiment 1 of a method of manufacturing a chip scale sensing chip package according to this present invention.

FIGS. 2A˜2F are cross-sectional views of the exemplary embodiment 2 of a method of manufacturing a chip scale sensing chip package according to this present invention.

FIGS. 3A˜3F are cross-sectional views of the exemplary embodiment 3 of a method of manufacturing a chip scale sensing chip package according to this present invention.

FIGS. 4A˜4F, 4E′ and 4F′ are cross-sectional views of the exemplary embodiment 4 of a method of manufacturing a chip scale sensing chip package according to this present invention.

FIGS. 5A˜5F are cross-sectional views of the exemplary embodiment 5 of a method of manufacturing a chip scale sensing chip package according to this present invention.

FIGS. 6A˜6F are cross-sectional views of the exemplary embodiment 6 of a method of manufacturing a chip scale sensing chip package according to this present invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific exemplary embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed.

### Exemplary Embodiment 1

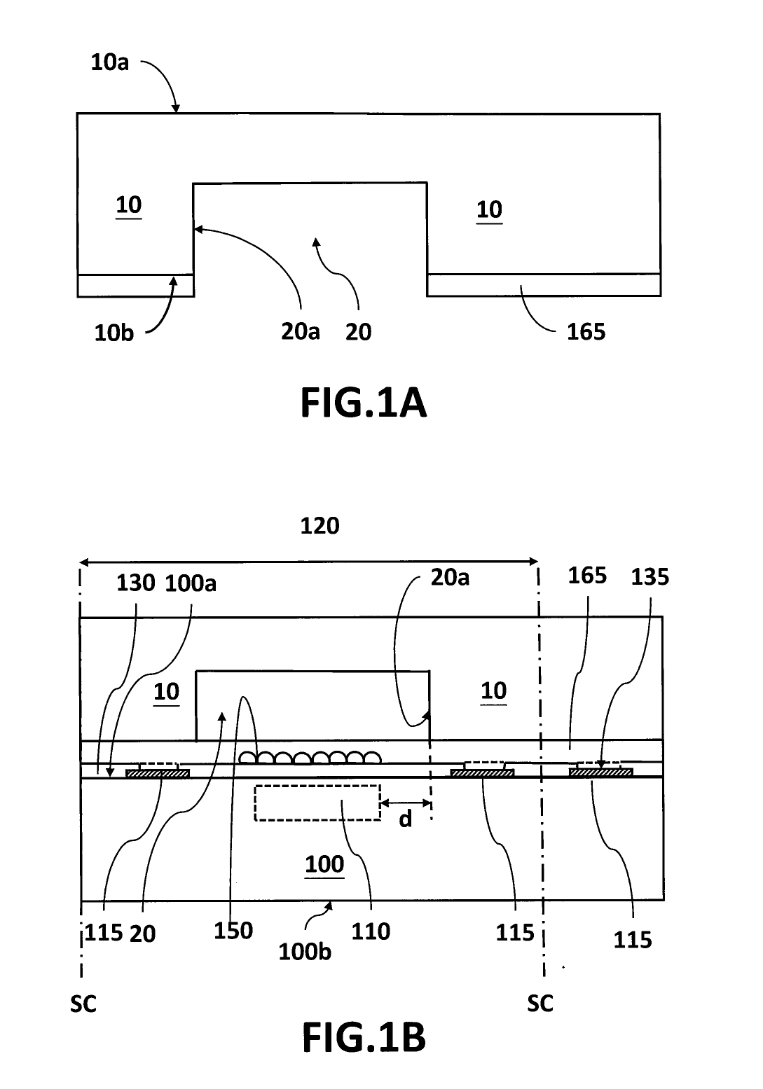

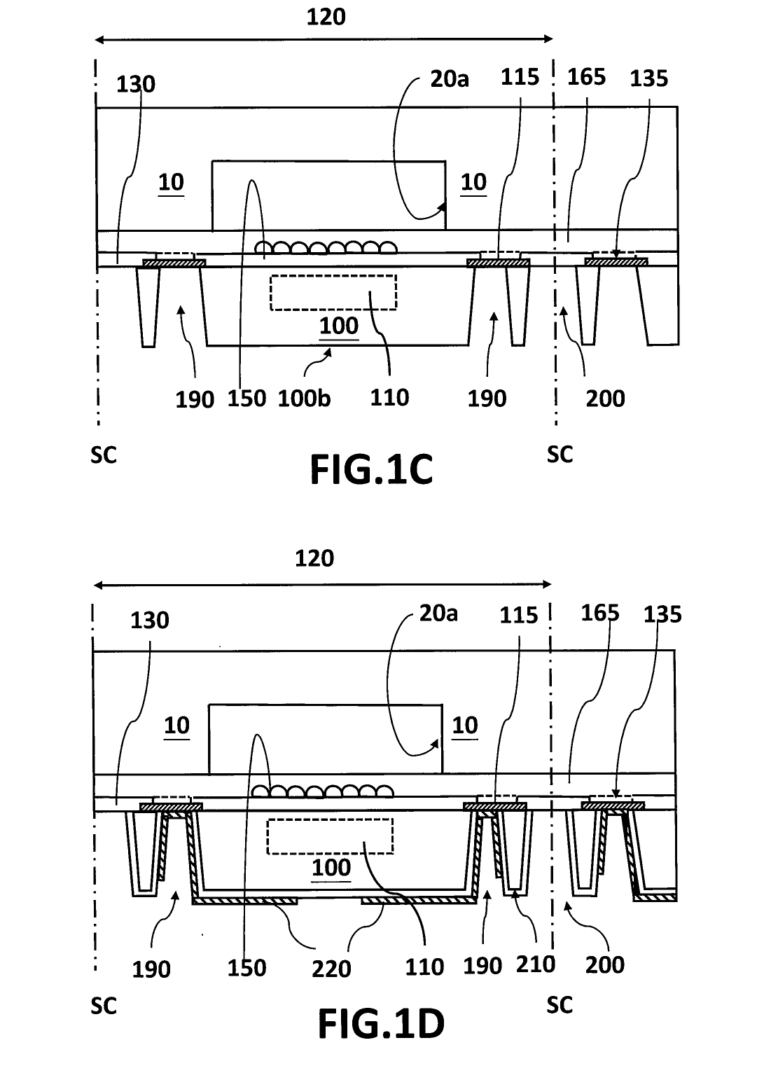

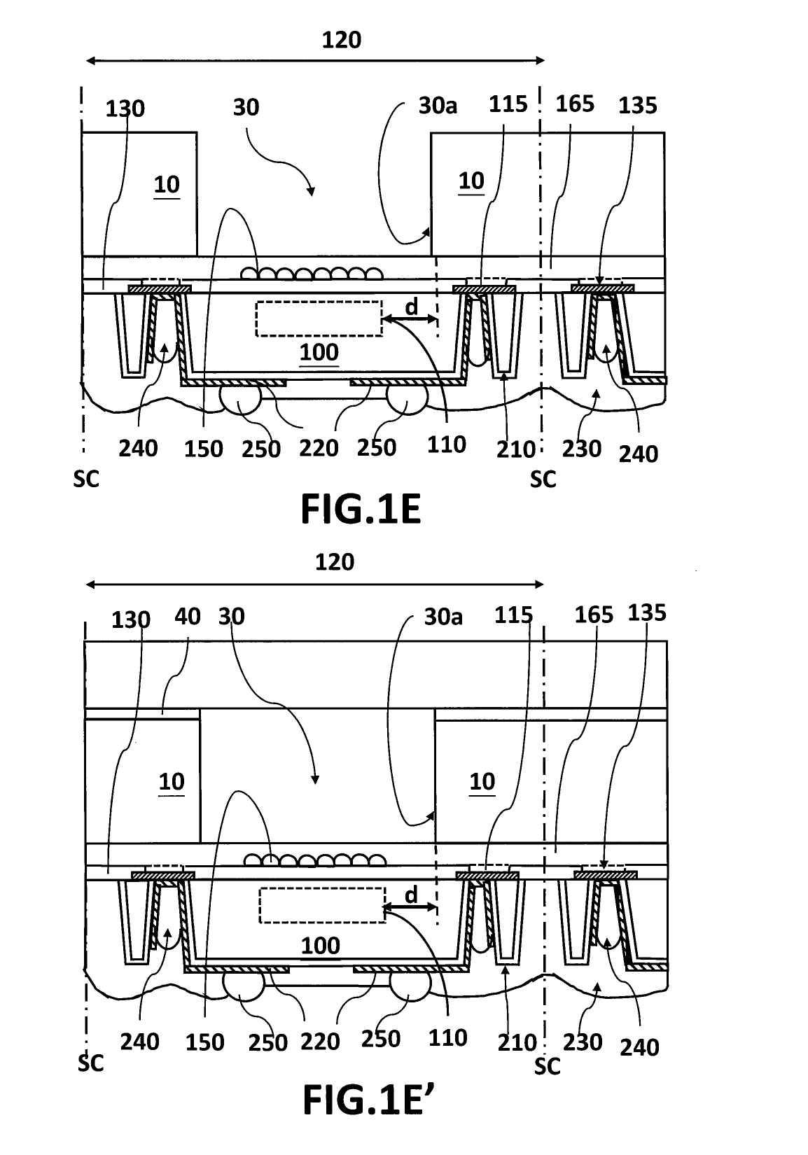

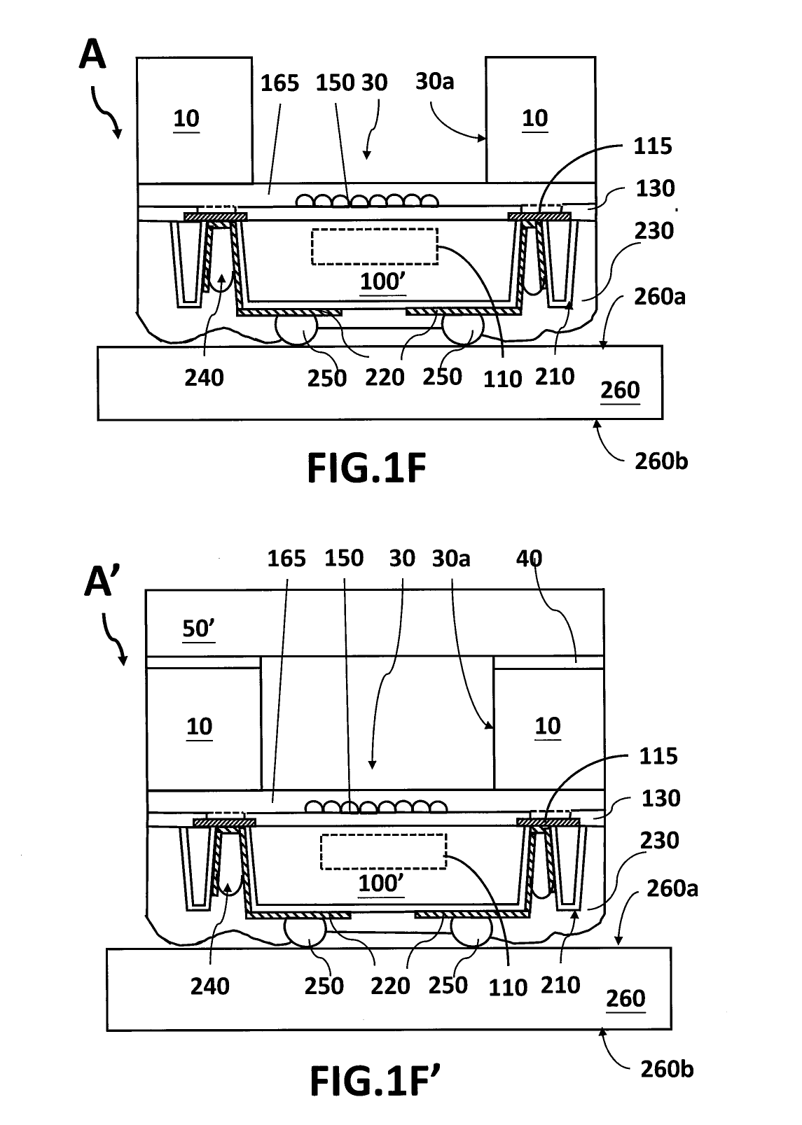

A detailed description of the chip scale sensing chip package and a method of manufacturing the same according to embodiment 1 of this invention is given below with reference to the accompany FIGS. 1A˜1F and FIGS. 1E′˜1F′.

First, please referring to FIG. 1A and FIG. 1B, a rectangle sensing device wafer 100 as shown in FIG. 1B was provided, wherein the sensing device wafer 100 has a first top surface 100a, a first bottom surface 100b and a plurality of chip regions 120. Each chip region comprises a sensing device 110 near the first top surface, a plurality of conductive pads 115 in the insulating layer 130 nearby the first top surface 100a, and an optical parts 150 such as a lens formed on the insulating layer 130 above the sensing device 110. Moreover, a plurality of openings 135 can be optionally formed to expose the top surface of conductive pads 115. Next, a spacing layer 10 with a thickness of about 200 μm as shown in FIG. 1A was provided, wherein the spacing layer 10 has a second top surface 10a and a second bottom surface 10b with a plurality of cavities 20. Each of the cavities 20 corresponds to each of the chip regions 120.

Next, a first adhesive 165 comprising photoresist, polyimide or epoxy resin was coated onto the second bottom surface 10b other than the cavities 20 of the spacing layer 10. Then, the spacing layer 10 was bonded to the sensing chip wafer 100 by sandwiching the first adhesive layer 165 between the second bottom surface 10b of the spacing layer 10 and the insulating layer 130 of the sensing chip wafer 100. Each sensing device 110 was surrounded by each cavity 20, and remained a predetermined distance d (d>0) with the inner wall 20a of each cavity 20.

Next, referring to FIG. 1C, the first bottom surface 100b of the sensing chip wafer 100 was thinned by etching, milling, grinding or polishing to reduce its thickness till less than 100 μm. Then, the first bottom surface 100b within each of the chip regions 120 was processed by photolithography and etching such as dry-etching, wet-etching, plasma-etching, reactive ions-etching or other suitable process to form a plurality of first through holes 190 exposing the conductive pad 115 and a plurality of second through holes 200 aligned with aligned with the scribe channel (SC).

Next, referring to FIG. 1D, an insulating layer 210 was deposited to overlay the first bottom surface 100b of the wafer 100, and the first through holes 190 and the second through holes 200 by means of spin-coating, CVD, PVD or other suitable processes. The insulating layer 210 of this present embodiment 1 comprises epoxy resin, inorganic material (e.g. silicon oxide, silicon nitride, silicon oxynitride, metal oxide or combination thereof), organic polymer (e.g. polyimide, benzo cyclo butane, poly-p-xylene, naphthalene polymer, chlorofluorocarbons or acrylic ester) or other suitable materials.

Next, the insulating layer 210 under each of the first through holes 190 was removed by photolithography and etching processes to expose corresponding conductive pad. Then, a patterned re-distribution layer (RDL) 220 was conformably formed on the insulating layer 210 by means of deposition processes (e.g. spin-coating, PVD, CVD, electroplating, electroless-deposition, or other suitable process), photolithography and etching processes. The RDL 220 is separated from the sensing device wafer 100 by the insulating layer 210, and in direct electrically connected to the exposed conductive pad 115 via the first through holes 190. The RDL 220 comprises aluminum, copper, gold, platinum, nickel or combination thereof, or conductive polymers, conductive ceramic materials (e.g. ITO or IZO) or other suitable conductive materials. Moreover, the RDL 220 can be an asymmetrical pattern. For example, the RDL 220 within each of the first through holes 190 does not extend onto the first bottom surface nearby the outer edge of chip region adjacent to the scribe channel.

Next, referring to FIG. 1E, a passivation layer 230 was deposited to overlay the second bottom surface 100b of the sensing device wafer 100, the first through holes 190 and the second through holes 200, and the RDL 220. The passivation layer 230 comprises epoxy resin, solder mask, inorganic material (e.g. silicon oxide, silicon nitride, silicon oxynitride, metal oxide or combination thereof), organic polymer (e.g. polyimide, benzo cyclo butane, poly-p-xylene, naphthalene polymer, chlorofluorocarbons or acrylic ester) or other suitable materials. The passivation layer 230 is used to partially fill the first through hole 190 to form a via 240 between the RDL 220 and the passivation layer 230 in each through hole 190. The boundary between the via 240 and the passivation layer 230 has an arc profile. Alternatively, the first through holes 190 can also be filled up with the passivation layer 230 in other embodiments.

Next, through holes (not shown) exposing part of the patterned RDL 220 were formed on the passivation layer 230 above the second substrate 100b of the sensing device wafer 100. Then, excess spacing layer 10 was removed in a direction from the second top substrate 10a to the second bottom substrate 10b by means of milling, grinding, or polishing till the bottom of each cavity 20 was penetrate through to generate an opening 30 exposing the sensing device 110, wherein each sensing device 110 remains a predetermined distance d (d>0) from the inner wall 30a of each opening 30.

Next, conductive structures 250 (e.g. solder balls, solder bumps or conductive pills) were formed in the through holes on the passivation 230 to electrically connect to the RDL 220. The conductive structures 250 comprises tin, lead, copper, gold, nickel or combination thereof.

Next, a scribing process was applied along aligned with the scribe channel to scribe the passivation layer 230, the insulating layer 130, the first adhesive 165 and the spacing layer 10, and generate a plurality of chip scale sensing chip packages A. Each of the chip scale sensing chip packages A comprises a rectangle chip scale sensing chip 100′ which has a sensing device 110 and a plurality of conductive pads 115 adjacent to the sensing device 110, and a spacing layer 10′ formed on the sensing chip 100′.

Moreover, a cap wafer 50 coated with a second adhesive layer 40 comprising photoresist, polyimide, tape or epoxy resin can be bonded to the spacing layer 10 before the scribing process described in paragraph [0048] as shown in FIG. 1E′ by sandwiching the second adhesive 40 between the cap wafer 50 and the spacing layer 10. Then, the same scribing process described in paragraph [0048] was applied to generate a plurality of chip scale sensing chip packages A′, wherein each chip scale sensing chip package A′ comprises a rectangle chip scale sensing chip 100′ and a rectangle cap layer 50′ with the same dimension as that of the sensing chip 100′. The cap wafer 50 comprises glass or other transparent materials with a hardness equal or greater than 7 such as aluminum, sapphire or ceramic materials.

Finally, please referring to FIGS. 1F and 1F′, a circuit board 260 with a top surface 260a and a bottom surface 260b was provided. Then, either the chip scale sensing chip package A or A′ was coupled to the top surface 260a of the circuit board 260, and electrically connected to the circuit board 260 through the conductive structures 250 comprising solder. The chip scale sensing chip package A or A′ can be coupled to the circuit board 260 after a reflow process was applied. Besides, passive devices such as inductors, capacitors, resistors or other electronic parts can be formed on the circuit board 260 by means of surface mount technology (SMT) before or after the chip scale sensing chip package A or A′ was coupled to the circuit board 260. Alternatively, abovementioned passive devices can be formed on the circuit board 260 together with the chip scale sensing chip package A or A′ during the same reflow process.

### Exemplary Embodiment 2

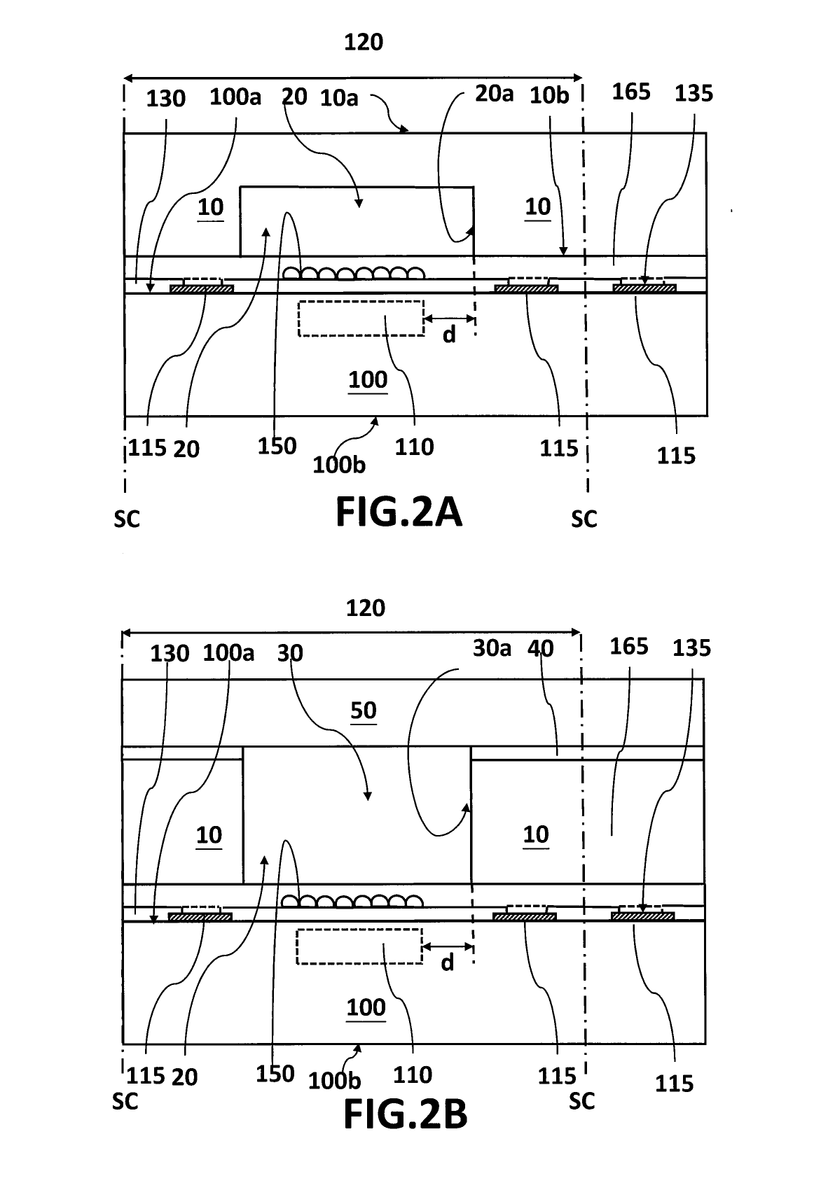

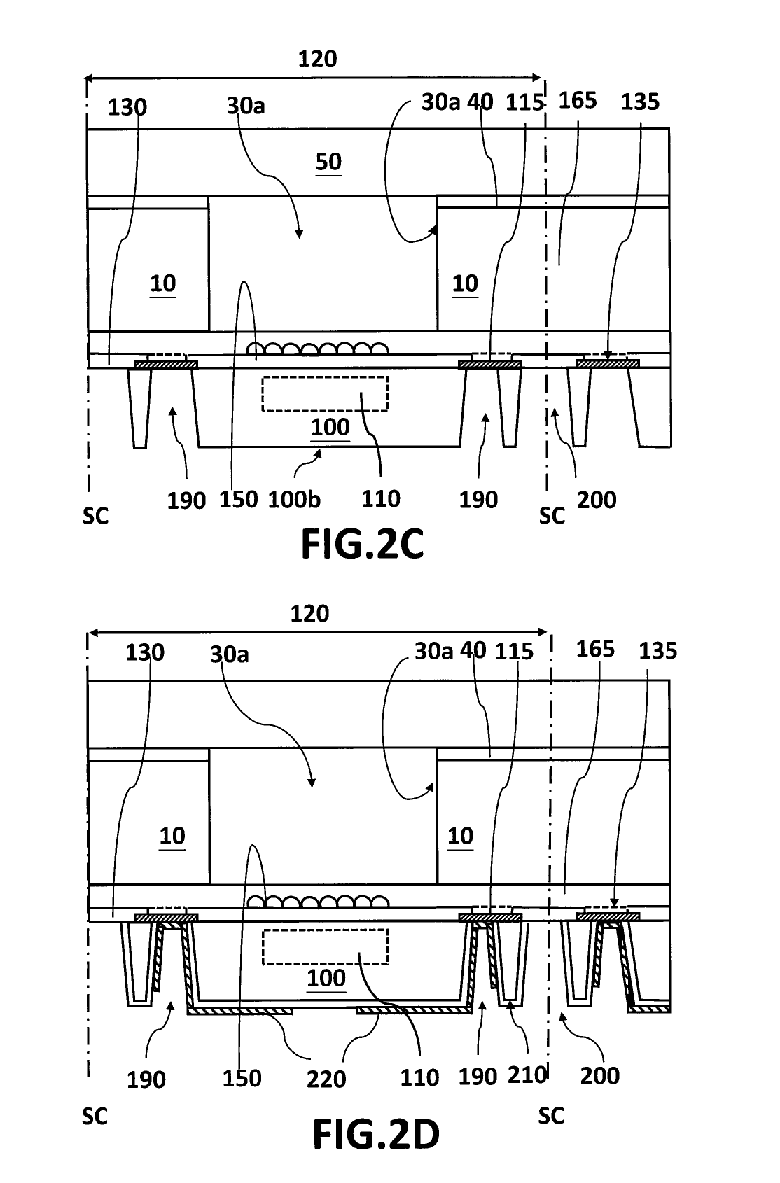

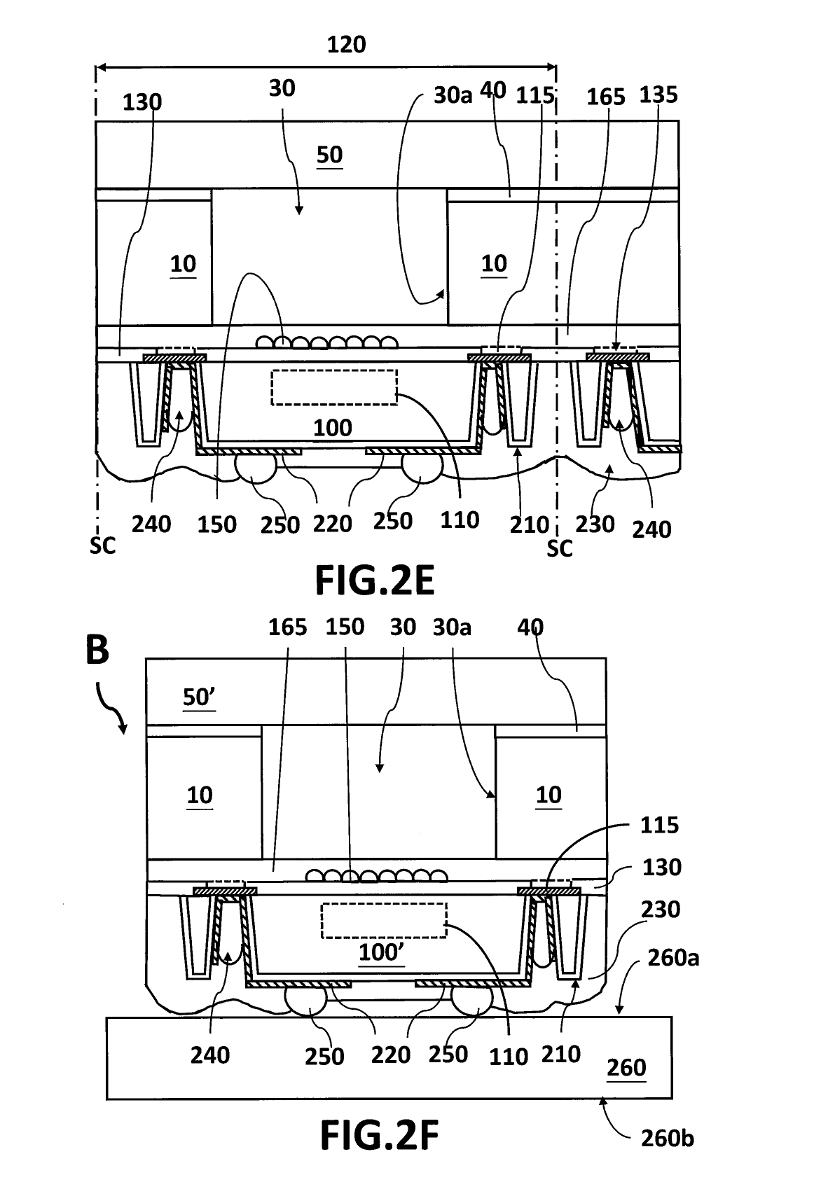

A detailed description of the chip scale sensing chip package and a method of manufacturing the same according to embodiment 2 of this invention is given below with reference to the accompany FIGS. 2A˜2F.

First, please referring to FIG. 2A, a sensing device wafer 100 and a spacing layer 10 as described in the embodiment 1 were provided.

Next, a first adhesive layer 165 comprising photoresist, polyimide or epoxy resin was coated on the second bottom substrate 10b other than the cavity 20 of the spacing layer 10. Then, the second bottom surface 10b of the spacing layer 10 was bonded to the first top surface 100a of the sensing device wafer 100 by sandwiching the first adhesive layer 165 therebetween. Each sensing device 110 was surrounded by each cavity 20, and remained a predetermined distance d (d>0) from the inner wall 20a of each cavity 20.

Next, referring to FIG. 2B, excess spacing layer 10 was removed in a direction from the second top substrate 10a to the second bottom substrate 10b by means of milling, grinding, or polishing till the bottom of each cavity 20 was penetrate through to generate an opening 30 exposing the sensing device 110, wherein each sensing device 110 remains a predetermined distance d (d>0) from the inner wall 30a of each opening 30. Then, a cap wafer 50 coated with a second adhesive layer 40 comprising photoresist, polyimide, tape or epoxy resin was bonded to the second top surface 10b of the spacing layer 10 by sandwiching the second adhesive layer 40 therebetween. The cap wafer 50 comprises glass or other transparent materials with a hardness equal or greater than 7 such as aluminum, sapphire or ceramic materials.

Next, referring to FIG. 2C, the first bottom surface 100b of the sensing device wafer 100 was thinned to about less than 100 μm by the same processes described in paragraph [0042]. Then, a plurality of first through holes 190 and second through holes 200 were formed by the same processes as described in paragraph [0042].

Next, referring to FIG. 2D, an insulating layer 210 and a patterned RDL 220 were formed on the first bottom surface 100b of the sensing device wafer 100 by the same processes as described in paragraphs [0043]˜[0044].

Next, referring to FIG. 2E, a passivation layer 230 was formed on the second surface 100b of the wafer 100 and filled into the first, second through holes to overlay the RDL 220 by the same processes described in paragraphs [0045]˜[0047]. Then, a plurality of conductive structures 250 were formed to electrically connect to the RDL 220.

Next, a plurality independent chip scale sensing chip packages B were generated by the same scribe processes as described in paragraph [0048]. Each of the chip scale sensing chip packages B comprises a rectangle chip scale sensing chip 100′ which has a sensing device 110 and a plurality of conductive pads 115 adjacent to the sensing device 110, and a spacing layer 10′ and a cap layer 50′ formed on the sensing chip 100′.

Finally, referring to FIG. 2F, a circuit board 260 with a top surface 260a and a bottom surface 260b was provided. Then, each of the chip scale sensing chip packages B was coupled to the top surface 260a of the circuit board 260, and electrically connected to the circuit board 260 through the conductive structures 250 comprising solder.

### Exemplary Embodiment 3

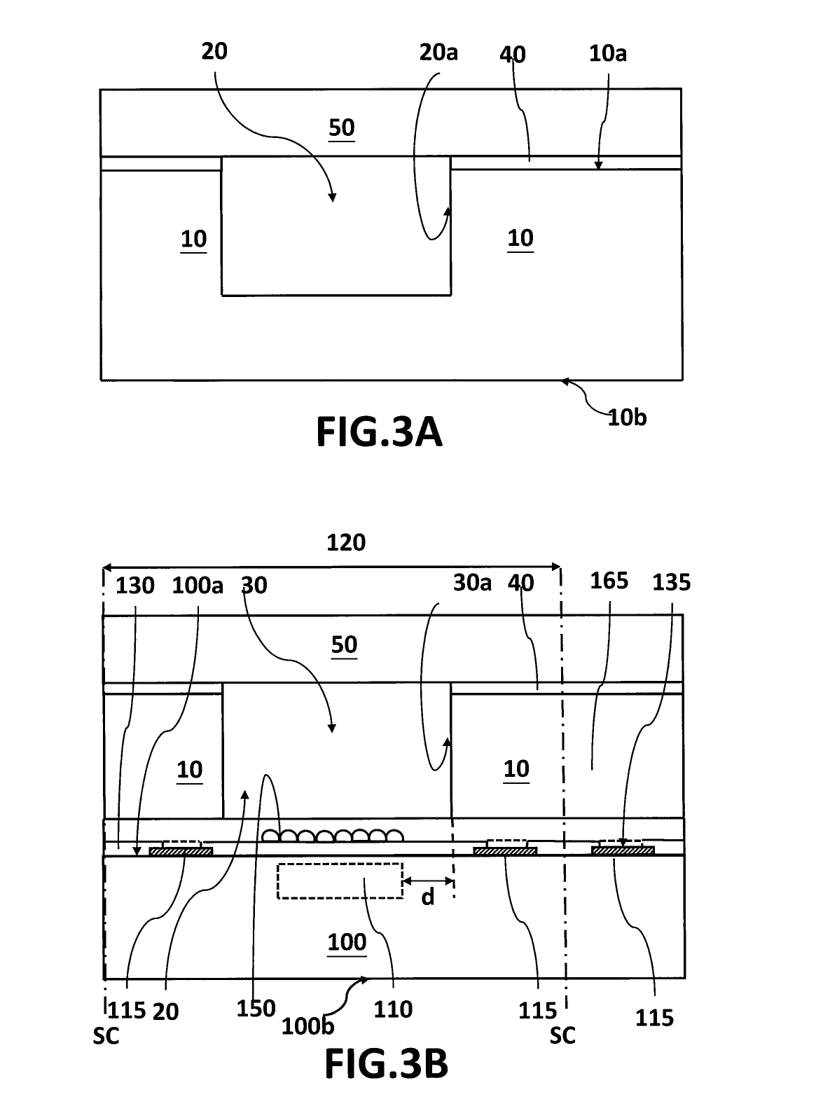

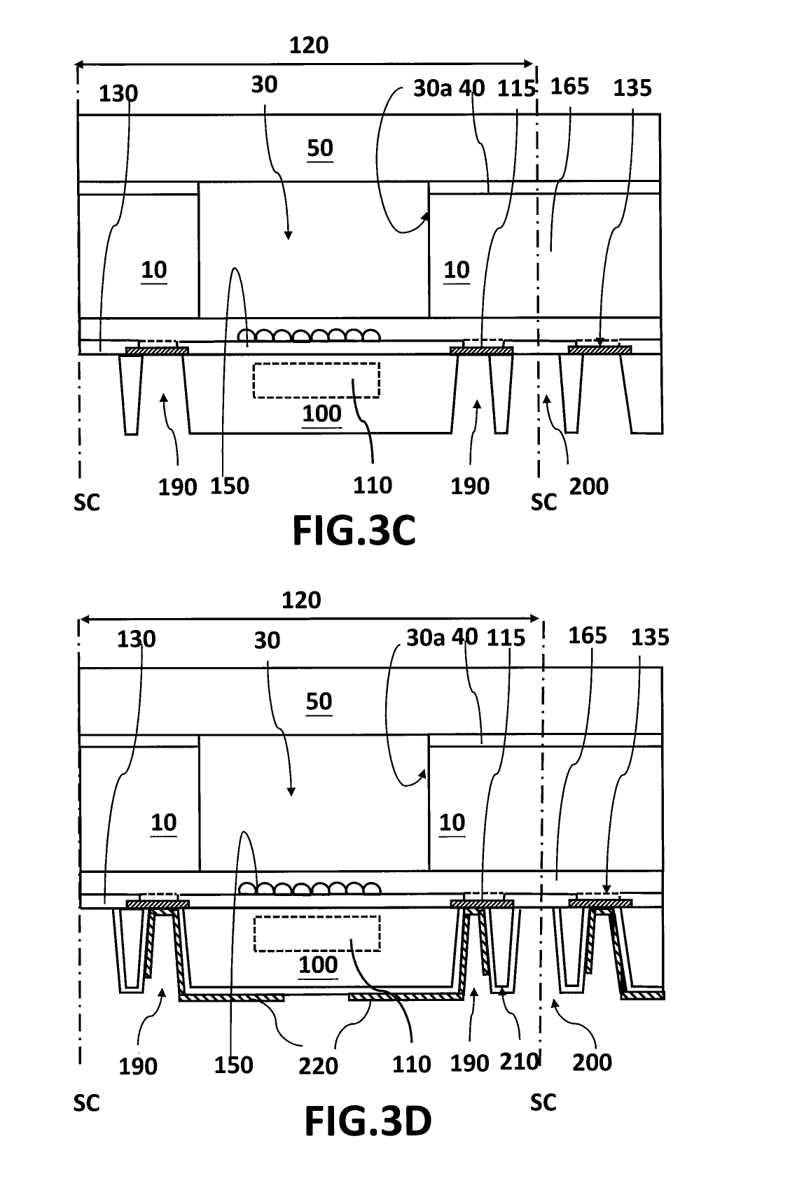

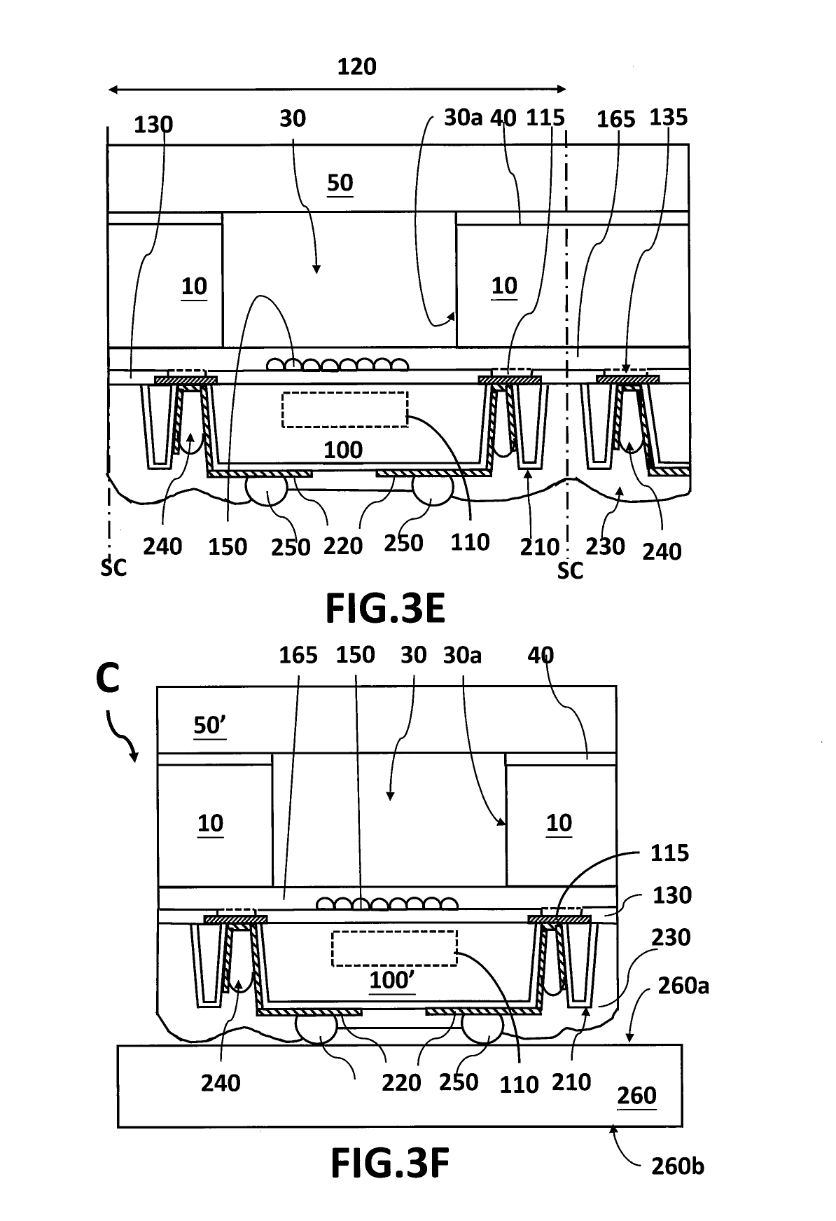

A detailed description of the chip scale sensing chip package and a method of manufacturing the same according to embodiment 3 of this invention is given below with reference to the accompany FIGS. 3A˜3F.

First, please referring to FIG. 3A and FIG. 3B, a sensing device wafer 100 as described in the embodiment 1 was provided. Then, a spacing layer 10 with a thickness of about 200 μm as shown in FIG. 3A was provided, wherein he spacing layer 10 has a second top surface 10a and a second bottom surface 10b with a plurality of cavities 20. Each of the cavities 20 corresponds to each of the chip regions 120.

Next, a cap wafer 50 coated with a second adhesive layer 40 comprising photoresist, polyimide, tape or epoxy resin was bonded to the second top surface 10a of the spacing layer 10 by sandwiching the second adhesive 40 therebetween. Then, excess spacing layer 10 was removed in a direction from the second bottom substrate 10b to the second top substrate 10a by means of milling, grinding, or polishing till the bottom of each cavity 20 was penetrate through to generate an opening 30 exposing the sensing device 110.

Next, a first adhesive layer 165 comprising photoresist, polyimide or epoxy resin was coated on the second bottom substrate 10b other than the opening 30 of the spacing layer 10. Then, the second bottom surface 10b of the spacing layer 10 was bonded to the first top surface 100a of the wafer 100 by sandwiching the first adhesive layer 165 therebetween. Each sensing device 110 was surrounded by each opening 30, and remained a predetermined distance d (d>0) from the inner wall 30a of each opening 30.

Next, referring to FIG. 3C, the first bottom surface 100b of the wafer 100 was thinned to about less than 100 μm by the same processes as described in paragraph [0042]. Then, a plurality of first through holes 190 and second through holes 200 were formed by the same processes as described in paragraph [0042].

Next, referring to FIG. 3D, an insulating layer 210 and a patterned RDL 220 were formed on the first bottom surface 100b of the wafer 100 by the same processes as described in paragraphs [0043]˜[0044].

Next, referring to FIG. 3E, a passivation layer 230 was formed on the second top surface 100b of the wafer 100, and filled into the first through holes 190 and the second through holes 200 to overlay the RDL 220 by the same processes described in paragraphs [0045]˜[0047]. Then, a plurality of conductive structures 250 were formed to electrically connect to the RDL 220.

Next, a plurality of independent chip scale sensing chip packages C were generated by the same scribe processes as described in paragraph [0048]. Each of the chip scale sensing chip packages C comprises a rectangle chip scale sensing chip 100′ which has a sensing device 110 and a plurality of conductive pads 115 adjacent to the sensing device 110, and a spacing layer 10′ and a cap layer 50′ formed on the sensing chip 100′.

Finally, referring to FIG. 3F, a circuit board 260 with a top surface 260a and a bottom surface 260b was provided. Then, each of the chip scale sensing chip packages C was coupled to the top surface 260a of the circuit board 260, and electrically connected to the circuit board 260 through the conductive structures 250 comprising solder.

### Exemplary Embodiment 4

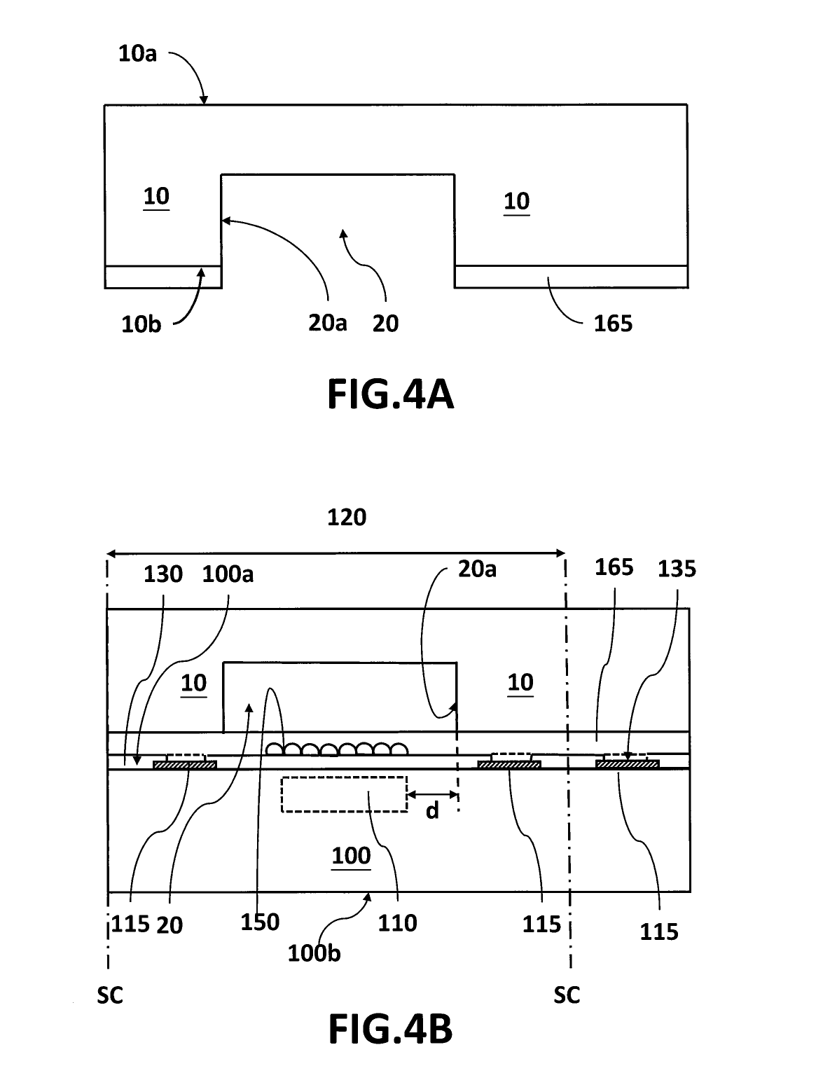

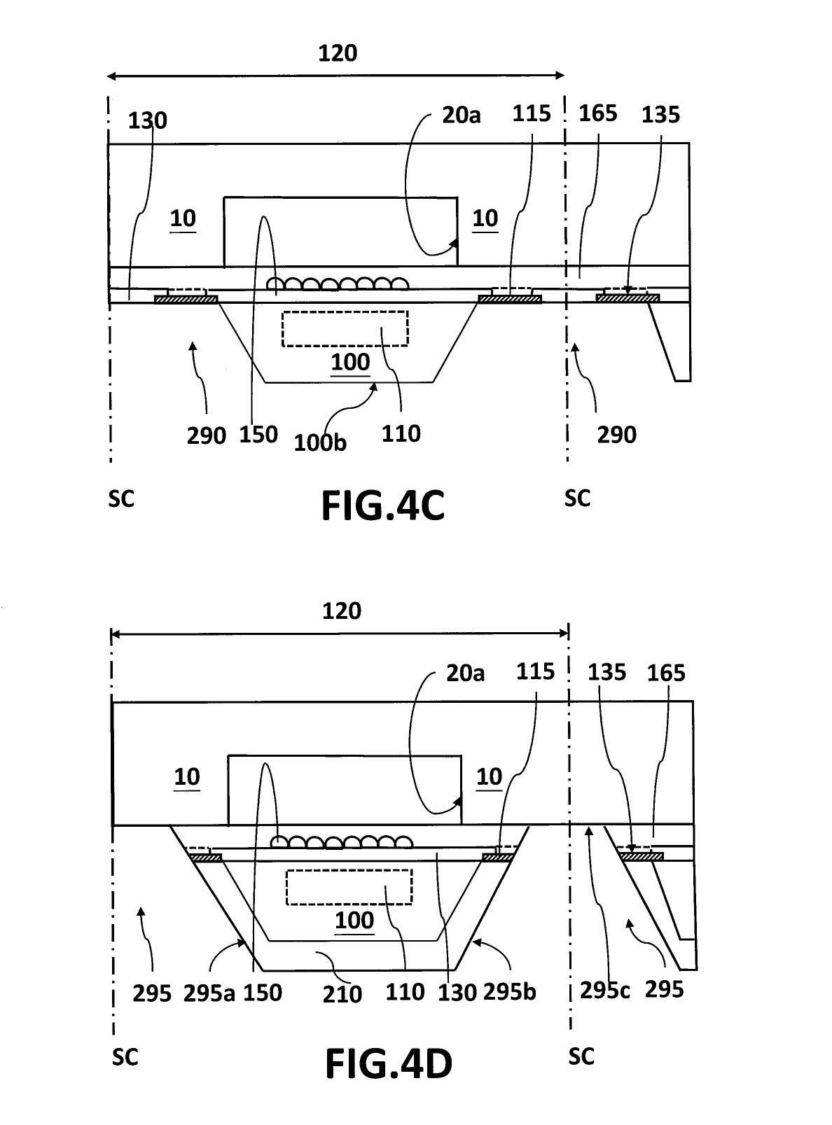

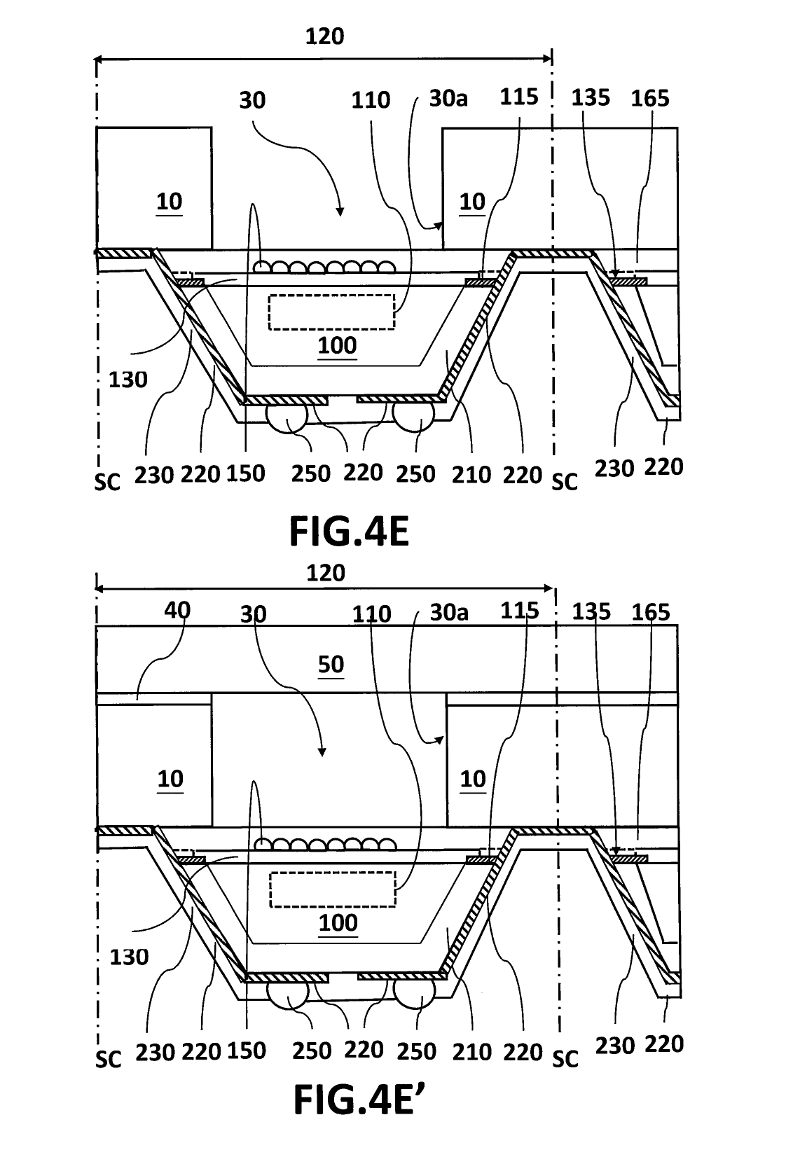

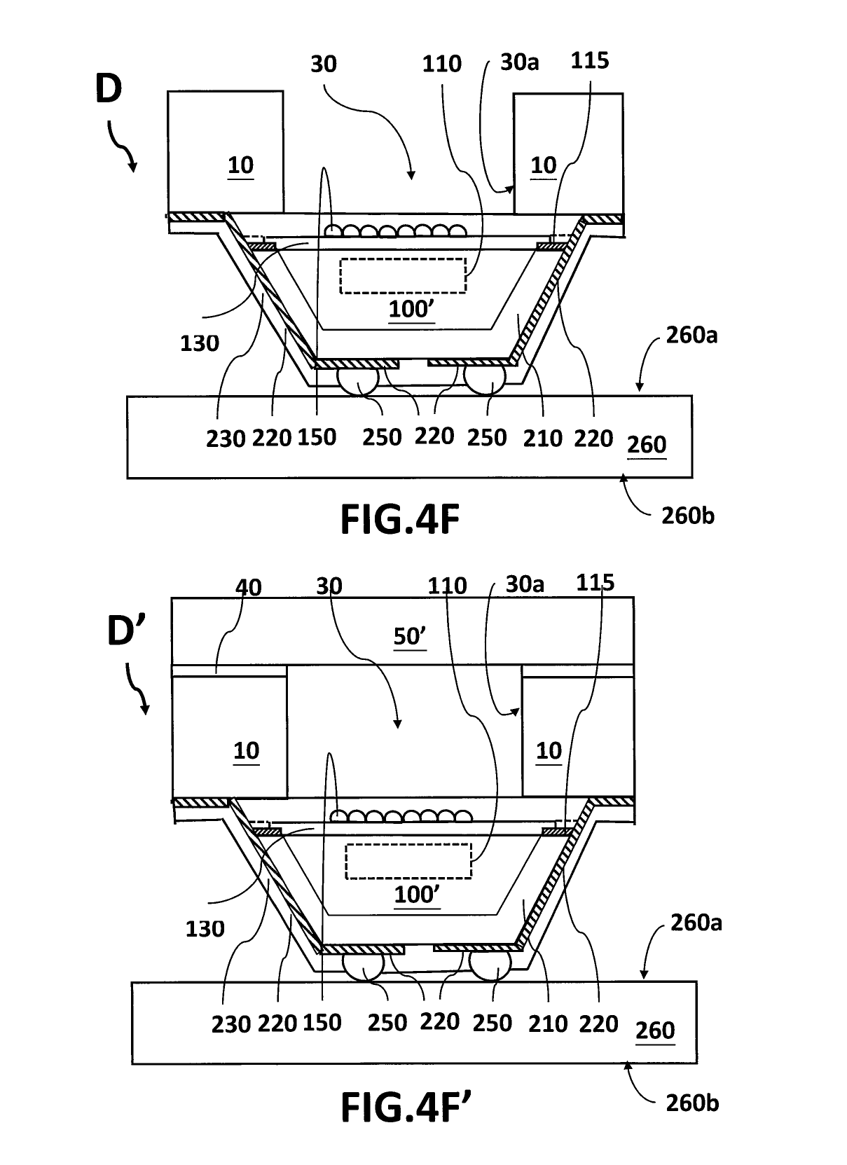

A detailed description of the chip scale sensing chip package and a method of manufacturing the same according to embodiment 4 of this invention is given below with reference to the accompany FIGS. 4A˜4F.

First, please referring to FIG. 4A and FIG. 4B, a sensing device wafer 100 as described in the embodiment 1 was provided.

Next, a first adhesive 165 comprising photoresist, polyimide or epoxy resin was coated on the second bottom surface 10b other than the cavities 20 of the spacing layer 10. Then, the spacing layer 10 was bonded to the sensing chip wafer 100 by sandwiching the first adhesive layer 165 therebetween. Each sensing device 110 was surrounded by each cavity 20, and remained a predetermined distance d (d>0) from the inner wall 20a of each cavity 20.

Next, referring to FIG. 4C, the first bottom surface 100b of the sensing device wafer 100 was thinned to about less than 100 μm by the processes described in paragraph [0042].

Then, a plurality of fourth through holes 290 exposing the conductive pads 115 were formed on the first bottom surface 100b of each chip region 120 by photolithography and etching processes such as dry-etching, wet-etching, plasma-etching, reactive ions-etching or other suitable processes.

Next, referring to FIG. 4D, an insulating layer 210 was deposited to overlay the first bottom surface 100b of the wafer 100 and the fourth through holes 290 by means of spin-coating, CVD, PVD or other suitable process. The insulating layer 210 of this present embodiment comprises epoxy resin, inorganic material (e.g. silicon oxide, silicon nitride, silicon oxynitride, metal oxide or combination thereof), organic polymer (e.g. polyimide, benzo cyclo butane, poly-p-xylene, naphthalene polymer, chlorofluorocarbons or acrylic ester) or other suitable materials.

Next, a plurality of notches 295 were formed by removing partial of the insulating layers 210 and 130, and partial of the conductive pads 115 nearby each of the fourth through holes 290, and partial of the first adhesive layer 165 by means of the so-called notching processes. Each of the notches comprises a first side wall 295a, a second sidewall and a bottom wall 295c adjoined therebetween, wherein both the first side wall 295a and the second sidewall 295b expose the edges of the conductive pads 115 thereon.

Next, referring to FIG. 4E, a patterned re-distribution layer (RDL) 220 was conformably formed on the insulating layer 210 by means of deposition processes (e.g. spin-coating, PVD, CVD, electroplating, electroless-deposition, or other suitable process), photolithography and etching processes. The RDL 220 conformably extended onto the first sidewall 295a, the second sidewall 295b and the bottom wall 295c of each notch 295. The RDL 220 is separated from the sensing device wafer 210 by the insulating layer 210, and directly or indirectly interconnect to the exposed edges of the conductive pads 115 on the first sidewall 295a and the second sidewall 295b. The RDL 220 comprises aluminum, copper, gold, platinum, nickel or combination thereof, or conductive polymers, conductive ceramic materials (e.g. ITO or IZO) or other suitable conductive materials.

Next, a passivation layer 230 was deposited to overlay the second bottom surface 100b of the sensing device wafer 100, and the first through holes 190 and the second through holes 200 by the same processes as described in paragraphs [0045]˜[0047]. Then, a plurality of openings 30 exposing the sensing devices were formed by removing excess spacing layer 10 to penetrate through the bottom wall of each cavity 20, wherein each sensing device 110 remained a predetermined distance d (d>0) from the inner wall 30a of each opening 30. Then, a plurality of conductive structures 250 were formed to electrically connect to the RDL 220.

Next, a scribing process was applied along aligned with the scribe channel SC to scribe the passivation layer 230, the insulating layer 130, and the spacing layer 10, and generate a plurality of chip scale sensing chip packages D. Each of the chip scale sensing chip packages D comprises a rectangle chip scale sensing chip 100′ which has a sensing device 110 and a plurality of conductive pads 115 adjacent to the sensing device 110, and a spacing layer 10′ formed on the sensing chip 100′.

Moreover, a cap wafer 50 coated with a second adhesive layer 40 comprising photoresist, polyimide, tape or epoxy resin to the second top surface 10b of the spacing layer can be bonded to the spacing layer 10 by sandwiching the second adhesive layer 40 therebetween before the scribing process as described in paragraph [0078] as shown in FIG. 4E′. Then, the same scribing process described in paragraph [0078] was applied to generate a plurality of independent chip scale sensing chip packages D′, wherein each chip scale sensing chip package D′ comprises a rectangle chip scale sensing chip 100′ and a rectangle cap layer 50′ with the same dimension as that of the sensing chip 100′. The cap wafer 50 comprises glass or other transparent materials with a hardness equal or greater than 7 such as aluminum, sapphire or ceramic materials.

Finally, please referring to FIGS. 4F and 4F′, a circuit board 260 with a top surface 260a and a bottom surface 260b was provided. Then, either the chip scale sensing chip package D or D′ was coupled to the top surface 260a of the circuit board 260, and electrically connected to the circuit board 260 through the conductive structures 250 comprising solder. The chip scale sensing chip package D or D′ can be coupled to the circuit board 260 after a reflow process was applied. Besides, passive devices such as inductors, capacitors, resistors or other electronic parts can be formed on the circuit board 260 by means of surface mount technology (SMT) before or after the chip scale sensing chip package D or D′ was coupled to the circuit board 260. Alternatively, abovementioned passive devices can be formed on the circuit board 260 together with the chip scale sensing chip package D or D′ during the same reflow process.

### Exemplary Embodiment 5

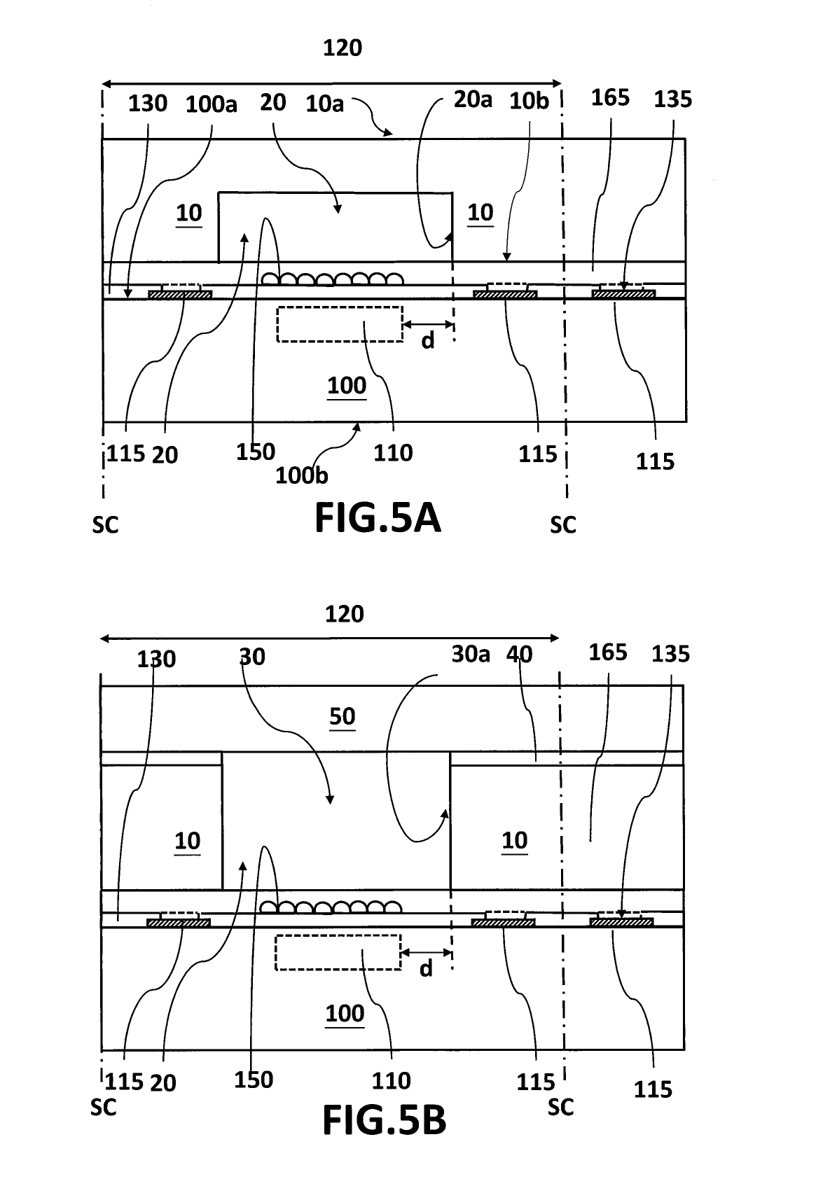

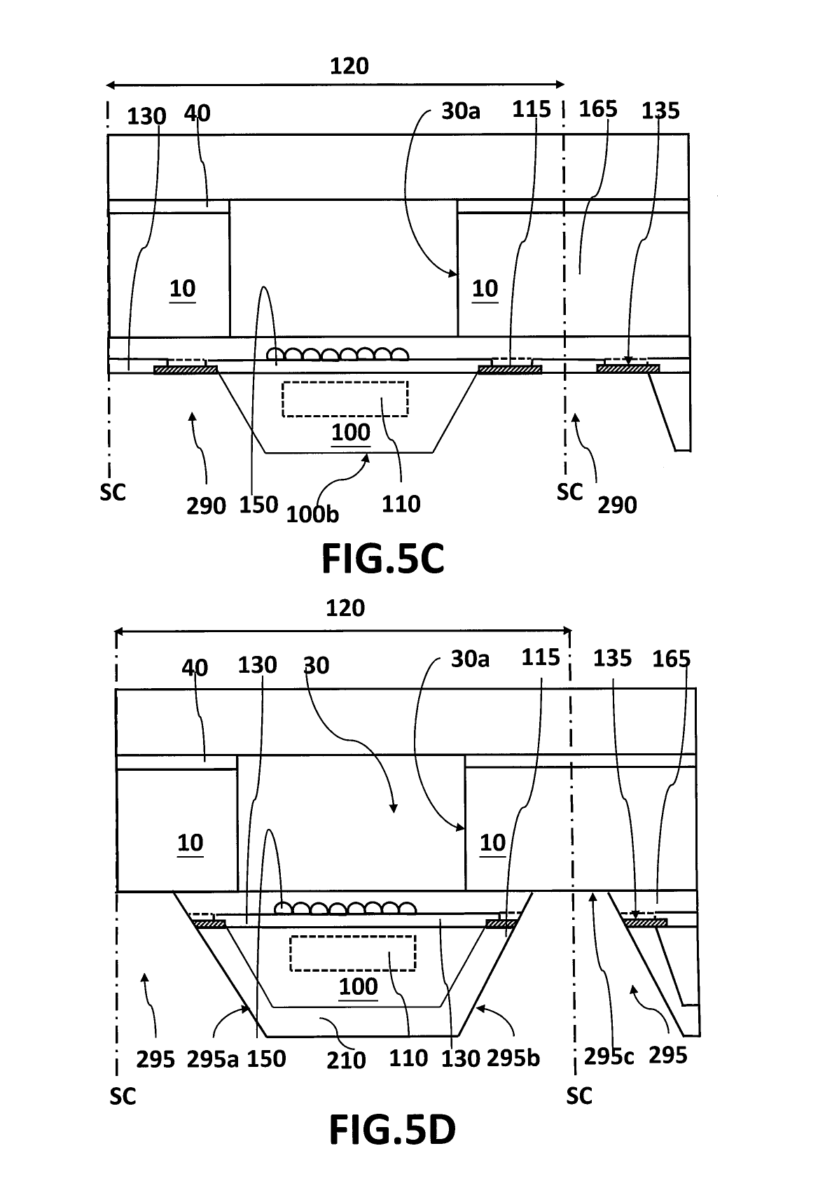

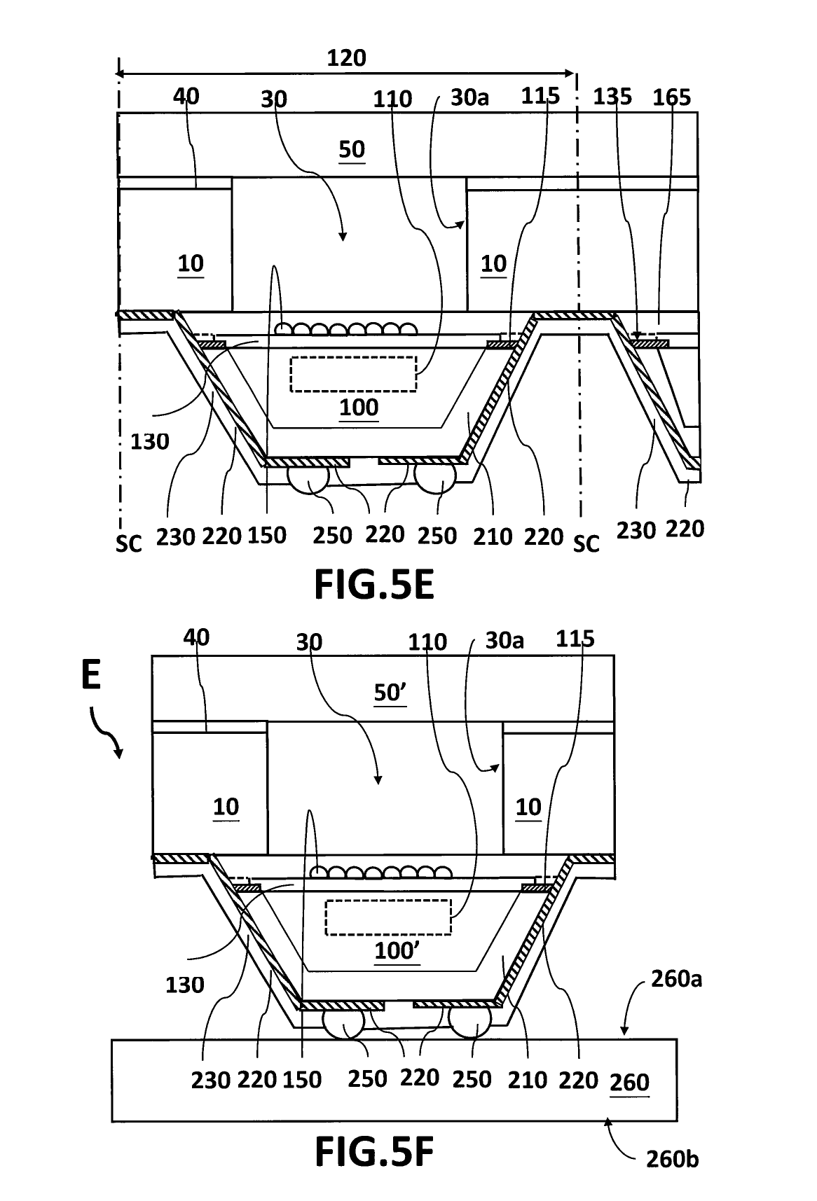

A detailed description of the chip scale sensing chip package and a method of manufacturing the same according to embodiment 5 of this invention is given below with reference to the accompany FIGS. 5A˜5F.

First, please referring to FIG. 5A, a sensing device wafer 100 and a spacing layer 10 as described in the embodiment 1 were provided.

Next, a first adhesive layer 165 comprising photoresist, polyimide or epoxy resin was coated onto the second bottom substrate 10b other than the cavity 20 of the spacing layer 10. Then, the second bottom surface 10b of the spacing layer 10 was bonded to the first top surface 100a of the wafer 100 by sandwiching the first adhesive layer 165 therebetween. Each sensing device 110 was surrounded by each cavity 20, and remained a predetermined distance d (d>0) from the inner wall 20a of each cavity 20.

Next, referring to FIG. 5B, excess spacing layer 10 was removed in a direction from the second top substrate 10a to the second bottom substrate 10b by means of milling, grinding, or polishing till the bottom of each cavity 20 was penetrate through to generate an opening 30 exposing the sensing device 110, wherein each sensing device 110 remains a predetermined distance d (d>0) from the inner wall 30a of each opening 30. Then, a cap wafer 50 coated with a second adhesive layer 40 comprising photoresist, polyimide, tape or epoxy resin was bonded to the second top surface 10a of the spacing layer 10 by sandwiching the second adhesive layer therebetween. The cap wafer 50 comprises glass or other transparent materials with a hardness equal or greater than 7 such as aluminum, sapphire or ceramic materials.

Next, referring to FIG. 5C, the first bottom surface 100b of the sensing device wafer 100 was thinned to about less than 100 μm by the process described in paragraph [0042]. Then, a plurality of fourth through holes 290 were formed on the first bottom surface 100b under each chip region 120 by the same processes as described in paragraph [0073].

Next, referring to FIG. 5D, an insulating layer 210 was deposited to overlay the first bottom surface 100b of the wafer 100 and the fourth through holes 290 by the same processes as described in paragraphs [0074].

Next, a plurality of notches 295 were formed by the same processes as described in paragraph [0075], wherein each of the notches comprises a first side wall 295a, a second sidewall and a bottom wall 295c adjoined therebetween, wherein both the first side wall 295a and the second sidewall 295b expose the edges of the conductive pads 115 thereon.

Next, referring to FIG. 5E, a patterned re-distribution layer (RDL) 220 was conformably formed on the insulating layer 210 by the same processes as described in paragraph [0076]. Then, a passivation layer 230 was formed on the first bottom surface 100b of the wafer 100 by the same processes as described in paragraph [0077] to overlay the RDL 220 and the conductive structures 250 (e.g. solder balls, solder bumps or conductive pills) electrically connected to the RDL 220.

Next, a scribing process as described in paragraph [0078] was applied to generate a plurality of independent chip scale sensing chip packages E.

Finally, please referring to FIG. 5F, a circuit board 260 with a top surface 260a and a bottom surface 260b was provided. Then, either the chip scale sensing chip package E was coupled to the top surface 260a of the circuit board 260, and electrically connected to the circuit board 260 through the conductive structures 250.

### Exemplary Embodiment 6

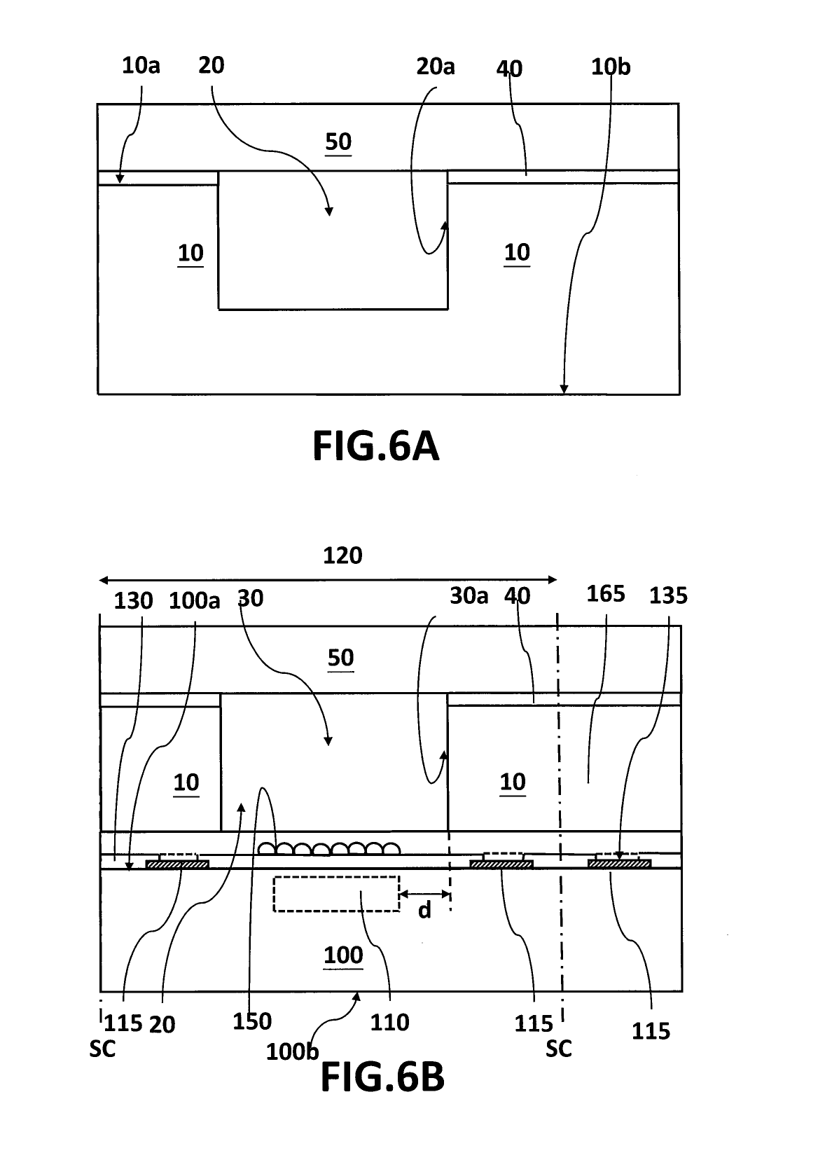

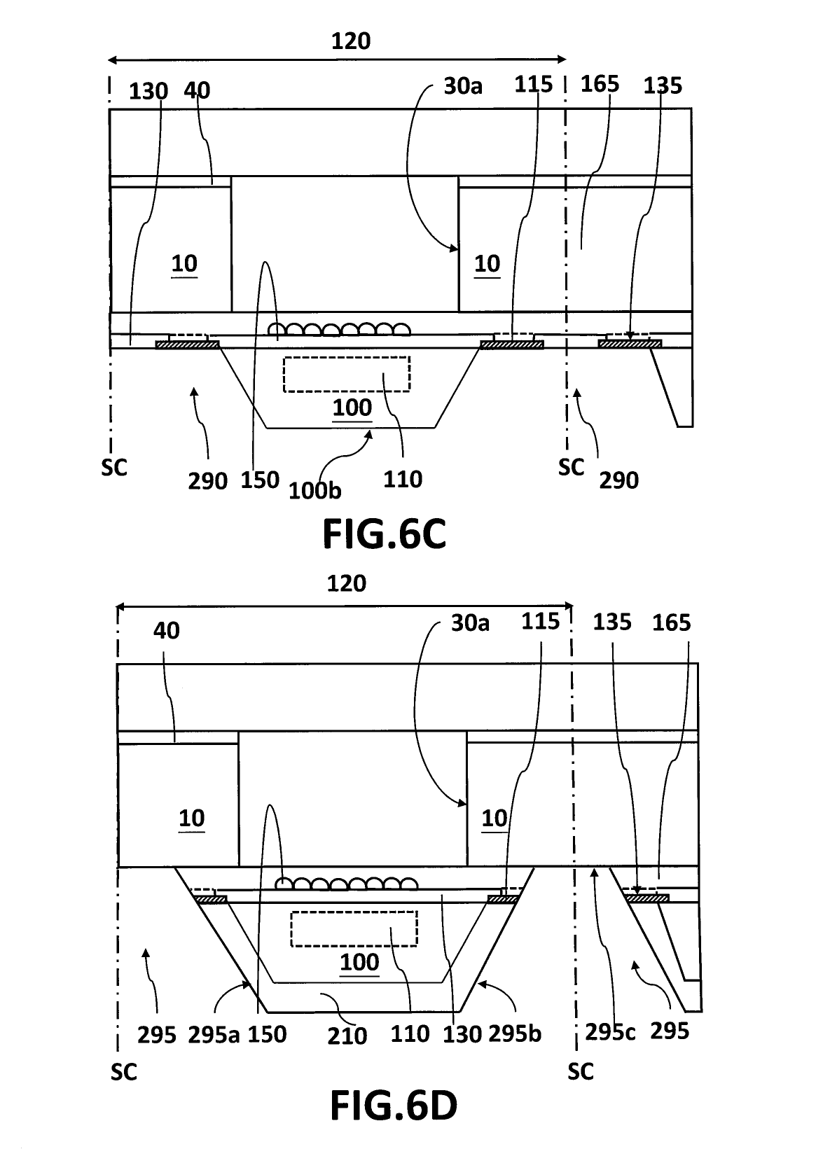

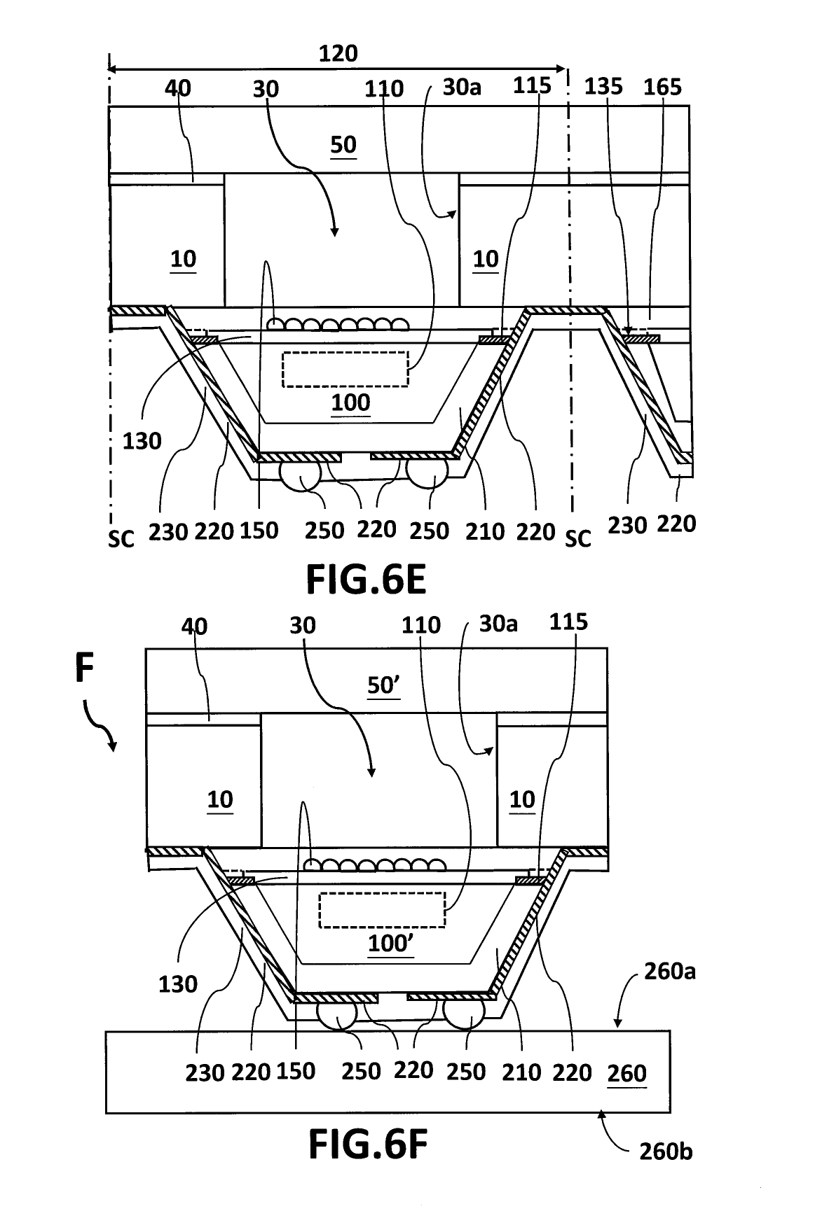

A detailed description of the chip scale sensing chip package and a method of manufacturing the same according to embodiment 6 of this invention is given below with reference to the accompany FIGS. 6A˜6F.

First, please referring to FIG. 6A and FIG. 6B, a sensing device wafer 100 as described in the embodiment 1 was provided. Then, a spacing layer 10 with a thickness of about 200 μm as shown in FIG. 6A was provided, wherein the spacing layer 10 has a second top surface 10a and a second bottom surface 10b with a plurality of cavities 20. Each of the cavities 20 corresponds to each of the chip regions 120.

Next, a cap wafer 50 coated with a second adhesive layer 40 comprising photoresist, polyimide, tape or epoxy resin was bonded to the second top surface 10a of the spacing layer 10 by sandwiching the second adhesive layer 40 therebetween. Then, excess spacing layer 10 was removed in a direction from the second bottom substrate 10b to the second top substrate 10a by means of milling, grinding, or polishing till the bottom of each cavity 20 was penetrate through to generate an opening 30 exposing the sensing device 110. Then, a first adhesive layer 165 comprising photoresist, polyimide or epoxy resin was coated on the second bottom substrate 10b other than the opening 30 of the spacing layer 10. Then, the second bottom surface 10b of the spacing layer 10 was bonded to the first top surface 100a of the wafer 100 by sandwiching the first adhesive layer 165 therebetween. Each sensing device 110 was surrounded by each opening 30, and remained a predetermined distance d (d>0) from the inner wall 30a of each opening 30.

Next, referring to FIG. 6C, the first bottom surface 100b of the wafer 100 was thinned to about less than 100 μm by the same processes as described in paragraph [0042]. Then, a plurality of fourth through holes 290 were formed on the first bottom surface 100b under each chip region 120 by the same processes as described in paragraph [0073].

Next, referring to FIG. 6D, an insulating layer 210 was deposited to overlay the first bottom surface 100b of the wafer 100 and the fourth through holes 290 by the same processes as described in paragraphs [0074].

Next, a plurality of notches 295 were formed by the same processes as described in paragraph [0075], wherein each of the notches comprises a first side wall 295a, a second sidewall and a bottom wall 295c adjoined therebetween, wherein both the first side wall 295a and the second sidewall 295b expose the edges of the conductive pads 115 thereon.

Next, referring to FIG. 6E, a patterned re-distribution layer (RDL) 220 was conformably formed on the insulating layer 210 by the same processes as described in paragraph [0076]. Then, a passivation layer 230 was formed on the first bottom surface 100b of the wafer 100 by the same processes as described in paragraph [0077] to overlay the RDL 220 and the conductive structures 250 (e.g. solder balls, solder bumps or conductive pills) electrically connected to the RDL 220.

Next, a scribing process as described in paragraph [0078] was applied to generate a plurality of independent chip scale sensing chip packages F.

Finally, please referring to FIGS. 6F, a circuit board 260 with a top surface 260a and a bottom surface 260b was provided. Then, either the chip scale sensing chip package F was coupled to the top surface 260a of the circuit board 260, and electrically connected to the circuit board 260 through the conductive structures 250.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip scale sensing chip package, comprising:
a sensing chip, having a first top surface and a first bottom surface opposite to each other, comprising:
a sensing device formed near the first top surface, and a plurality of conductive pads formed near the first top surface and adjacent to the sensing device;
a plurality of first through holes formed on the first bottom surface, and each of the first through holes exposing its corresponding conductive pad;
a plurality of conductive structures, formed on the first bottom surface; and
a re-distribution layer, overlaying the first bottom surface and the first through holes to connect to each of the conductive pads and each of the conductive structures;
a spacing layer, surrounding the sensing device, formed on the sensing chip, wherein the spacing layer having a second top surface and a second bottom surface opposite to each other, and an opening through the second top surface and the second bottom surface, and the inner wall of the opening remains a predetermined distance d (d>0) with the sensing device; and
a first adhesive layer sandwiched between the second bottom surface of the spacing layer and the first top surface of the sensing chip.

2. The chip scale sensing chip package as claimed in claim 1, wherein the spacing layer is thicker than the sensing chip.

3. The chip scale sensing chip package as claimed in claim 2, wherein the spacing layer comprises the material selected from one or more members of the group consisting of silicon, aluminum nitride, glass and ceramic materials.

4. The chip scale sensing chip package as claimed in claim 1, wherein the first adhesive layer comprises the material selected from one or more members of the group consisting of photoresist, polyimide and epoxy resin.

5. The chip scale sensing chip package as claimed in claim 1, further comprising a cap layer formed on the spacing layer, and a second adhesive layer sandwiched between the cap layer and the second top surface of the spacing layer.

6. The chip scale sensing chip package as claimed in claim 5, wherein the cap layer comprise the material selected from one or more members of the group consisting of glass, sapphire and aluminum nitride and ceramic materials.

7. The chip scale sensing chip package as claimed in claim 5, wherein the second adhesive layer comprises the material selected from one or more members of the group consisting of photoresist, polyimide and epoxy resin.

8. The chip scale sensing chip package as claimed in claim 1, wherein the cross-sectional area of each first through holes increases from the first top surface to the first bottom surface.

9. The chip scale sensing chip package as claimed in claim 1, wherein the conductive structures comprise solder balls, solder bumps and conductive pillars.

10. A chip scale sensing chip package, comprising:
a sensing chip, having a first top surface, an opposite first bottom surface, and a first sidewall and a second sidewall respectively adjoined to the first top surface and the first bottom surface, comprising:
a sensing device formed near the first top surface, and a plurality of conductive pads formed near the first top surface and adjacent to the sensing device, wherein the first side wall and the second side wall respectively exposes the edge of each conductive pad;
a plurality of conductive structures, formed on the first bottom surface; and
a re-distribution layer, overlaying the first bottom surface and the first, second side walls to connect to each of the conductive pads and each of the conductive structures;
a spacing layer, surrounding the sensing device, formed on the sensing chip wherein the spacing layer having a second top surface and a second bottom opposite to each other, and an opening through the second top surface and the second bottom surface, and the inner wall of the opening remains a predetermined distance d (d>0) with the sensing device; and
a first adhesive layer sandwiched between the second bottom surface of the spacing layer and the first top surface of the sensing chip.

11. The chip scale sensing chip package as claimed in claim 10, wherein the spacing layer is thicker than the sensing chip.

12. The chip scale sensing chip package as claimed in claim 11, wherein the spacing layer comprises the material selected from one or more members of the group consisting of silicon, aluminum nitride, glass and ceramic materials.

13. The chip scale sensing chip package as claimed in claim 10, wherein the first adhesive layer comprises the material selected from one or more members of the group consisting of photoresist, polyimide and epoxy resin.

14. The chip scale sensing chip package as claimed in claim 10, further comprising a cap layer formed on the spacing layer, and a second adhesive layer sandwiched between the cap layer and the second top surface of the spacing layer.

15. The chip scale sensing chip package as claimed in claim 14, wherein the cap layer comprises the material selected from one or more members of the group consisting of glass, sapphire and aluminum nitride and ceramic materials.

16. The chip scale sensing chip package as claimed in claim 14, wherein the second adhesive layer comprises the material selected from one or more members of the group consisting of photoresist, polyimide and epoxy resin.

17. The chip scale sensing chip package as claimed in claim 10, wherein the conductive structures comprise solder balls, solder bumps and conductive pillars.
